(19) United States
(12) Patent Application Publication
(10) Pub. No.: US 2025/0258212 A1
(43) Pub. Date: Aug. 14, 2025

(54) PARTIAL DISCHARGE DETECTION APPARATUS AND DETECTION METHOD

(71) Applicant: Fluke Corporation, Everett, WA (US)

(72) Inventors: Zhangyan Zhao, Shanghai (CN); Guofeng Che, Shanghai (CN); Zhihong Li, Shanghai (CN)

(21) Appl. No.: 19/048,554

(22) Filed: Feb. 7, 2025

(30) Foreign Application Priority Data
Feb. 9, 2024 (CN) 202410180293.X

(51) Int. Cl. G01R 31/12; G01R 31/14

(52) U.S. Cl. CPC G01R 31/1209; G01R 31/14

(57) ABSTRACT

A partial discharge detection apparatus and a detection method for monitoring partial discharges of an electrical device within a site. In at least one embodiment, the apparatus includes an acoustic detection module disposed within the site and configured to face the electrical device so as to detect a sound wave generated by the electrical device and generate a corresponding acoustic signal. The apparatus further includes a control module coupled to the acoustic detection module to receive the acoustic signal. The control module is configured to determine, on the basis of the acoustic signal, whether a partial discharge has occurred in the electrical device. The acoustic detection module and the control module are communicatively coupled but electrically isolated from each other.

### BACKGROUND

### Technical Field

The present disclosure relates to detection technology, and relates more specifically to a partial discharge detection apparatus and a detection method using the apparatus.

### Description of the Related Art

In recent years, new energy generation such as wind power and solar power has been greatly developed. Compact substations are usually used in wind farms or solar power plants to achieve grid connection of electric energy. A compact substation integrates a transformer, a high-voltage switching device, a low-voltage power distribution device, and the like to perform a step-up or step-down operation on electric energy. However, a partial discharge may occur in the compact substation due to the influence of factors such as long-term operation and moisture intrusion. The partial discharge is usually caused by a small defect of a dielectric material in a high-voltage electrical device and may cause tiny repetitive discharges. The partial discharge may propagate and grow over time. If the partial discharge is not promptly handled, it may cause serious consequences such as device failure, arc flashes, etc.

Therefore, it is desirable to provide an apparatus capable of performing early detection of partial discharges.

### BRIEF SUMMARY

The present disclosure provides a partial discharge detection apparatus that can automatically perform early detection of partial discharges so as to promptly discover a partial discharge and issue an alarm, thereby reducing the risk of device failure.

According to an aspect of the present disclosure, there is provided a partial discharge detection apparatus for detecting partial discharges using an acoustic sensor, wherein the apparatus does not depend on an operator carrying same to the vicinity of an electrical device for testing. For example, the partial discharge detection apparatus can be placed in a high-voltage space of a compact substation, such as a wind farm or a solar power plant, to continuously monitor partial discharges of various devices therein, and can send an alarm to a remote device when a partial discharge is detected. The acoustic sensor detects a sound wave instead of an electrical signal, which can effectively avoid electromagnetic interference in the high-voltage space and discover an early partial discharge of the electrical device. By way of data continuously collected from the partial discharge detection apparatus, the wind farm or the solar power plant can actively detect and identify the partial discharge of the device in the compact substation and predict the future potential abnormal state of the device, thereby reducing the risk, and achieving predictive maintenance of the compact substation. Furthermore, since the partial discharge detection apparatus can be deployed at high-voltage sites, it is possible to avoid or reduce manual inspection, which greatly improves detection efficiency.

According to an aspect of the present disclosure, there is provided a partial discharge detection apparatus. The partial discharge detection apparatus comprises an acoustic detection module and a control module. The acoustic detection module is disposed inside a high-voltage site and is configured to face a monitored electrical device to detect a sound wave generated by the electrical device and generate a corresponding acoustic signal. The control module is coupled to the acoustic detection module to receive the acoustic signal, and the control module is configured to determine, on the basis of the acoustic signal, whether a partial discharge has occurred in the monitored electrical device. The acoustic detection module and the control module of the partial discharge detection apparatus are communicatively coupled but electrically isolated from each other. The acoustic detection module and the control module may be two separately packaged components. For example, they are disposed in two different housings. According to use requirements, when the acoustic detection module is disposed inside a high-voltage site, the control module may be disposed outside the high-voltage site. For example, the acoustic detection module may be disposed in a high-voltage chamber of a pad-mounted transformer, and the control module may be disposed in a transformer chamber of the pad-mounted transformer. The two are connected by way of a fiber optic cable or in a similar isolated coupling manner, so that the high-voltage chamber is electrically isolated from the external environment and the device, and the electrical safety of the control module is also ensured.

In some examples, the control module is further configured to generate an alarm notification in response to determining that a partial discharge has occurred in the electrical device. In some examples, the control module is further configured to send the alarm notification to a remote device. This enables relevant personnel to be promptly informed of the occurrence of the partial discharge and handle same.

In some embodiments, the control module may comprise a signal processing module and a communication module. The signal processing module is coupled to the acoustic detection module to receive the acoustic signal and configured to determine, on the basis of the acoustic signal, whether a partial discharge has occurred in the electrical device, and to generate the alarm notification in response to determining that a partial discharge has occurred in the electrical device. The communication module is coupled to the signal processing module to receive the alarm notification, and the communication module is communicatively coupled to the remote device to send the alarm notification to the remote device.

In some embodiments, the control module, or more specifically, the signal processing module therein, is further configured to evaluate, on the basis of the acoustic signal, a type and/or intensity of the partial discharge occurring in the electrical device, and to send the evaluated type and/or intensity of the partial discharge to the remote device via the communication module. As such, an operator using the remote device can determine the possibility and severity of the partial discharge on the basis of these pieces of information, and formulate a corresponding handling method.

In some embodiments, the partial discharge detection apparatus further comprises a battery, which may be disposed in the same housing as the acoustic detection module, and configured to supply power to the acoustic detection module. Power is supplied to the acoustic detection module by way of the battery instead of an AC power supply, which is advantageous when the partial discharge detection is disposed in the high-voltage chamber of the pad-mounted transformer, because there may be no power supply available for external devices in the high-voltage chamber of the pad-mounted transformer, or it may prevent the power supply (in which a fault may occur) in the high-voltage chamber from affecting the operation of the acoustic monitoring module (e.g., stopping operation or causing damage).

In some embodiments, the partial discharge detection apparatus further comprises a power supply module, which may be disposed in the same housing as the control module and configured to supply power to the control module. The power supply module is configured to be coupled to an AC power supply used for supplying power to the electrical device within the high-voltage site, so as to receive power from the AC power supply to supply power to the control module. The control module, or more specifically, the signal processing module therein, may comprise a frequency detection circuit, configured to detect operating frequency information of the AC power supply, wherein the control module is further configured to determine, on the basis of the acoustic signal and the operating frequency information, whether a partial discharge has occurred in the electrical device. Since the partial discharge phenomenon is closely related to the frequency/phase of the AC power supply that supplies power to the electrical device, the use of the frequency detection circuit to acquire state information of the AC power supply helps to improve the accuracy of detecting the partial discharge.

In some embodiments, the acoustic detection module comprises a plurality of acoustic sensors, the plurality of acoustic sensors being disposed to respectively face different parts of the electrical device to respectively detect sound waves generated by the electrical device. In some embodiments, the acoustic detection module comprises at least one acoustic sensor, the at least one acoustic sensor being mounted on a rotatable base to be rotated by the rotatable base to face different parts of the electrical device, thereby separately detecting, from different directions, the sound wave generated by the electrical device. In some embodiments, the acoustic detection module comprises a sensor array having a plurality of acoustic sensors, the sensor array being configured to use a beamforming technique to detect the sound wave generated by the electrical device; and the control module, or more specifically, the signal processing module therein, may be further configured to determine, on the basis of the acoustic signal corresponding to the sound wave detected using the beamforming technique, a part of the electrical device where the partial discharge has occurred. The operator may select a configuration mode of a corresponding acoustic detection module according to the situation of a tested high-voltage site and an electrical device therein, which can effectively improve a sensing angle and a sensing distance of a sound signal, and is thus advantageous in a scenario in which there are a plurality of electrical devices to be monitored in a high-voltage space or there are a plurality of partial discharge risk points to be monitored in one electrical device.

In some embodiments, the acoustic detection module is configured to receive an operating mode instruction from the control module, or more specifically, the signal processing module therein, the operating mode instruction comprising a continuous detection mode instruction or an intermittent detection mode instruction, wherein the acoustic detection module is configured to detect, at a first detection frequency and in response to receiving the continuous detection mode instruction, the sound wave generated by the electrical device; and the acoustic detection module is configured to detect, at a second detection frequency and in response to receiving the intermittent detection mode instruction, the sound wave generated by the electrical device, wherein the first detection frequency is higher than the second detection frequency. For example, the control module, or more specifically, the signal processing module therein, is further configured to generate the intermittent detection mode instruction after the apparatus is powered on, and to send the intermittent detection mode instruction to the acoustic detection module. For example, the control module, or more specifically, the signal processing module therein, is further configured to generate the continuous detection mode instruction in response to receiving an abnormal acoustic signal, and to send the continuous detection mode instruction to the acoustic detection module. For example, the control module, or more specifically, the signal processing module therein, is further configured to, when the acoustic detection module is in the continuous detection mode and no partial discharge of the electrical device has been found within a predetermined operating time, generate the intermittent detection mode instruction, and send the intermittent detection mode instruction to the acoustic detection module. The acoustic detection module of the partial discharge detection apparatus may have different operating modes. When the risk of partial discharge is high, detection can be performed at a higher frequency, and when the risk of partial discharge is low, detection can be performed at a lower frequency, which is advantageous for saving power (especially when an independent power supply such as a battery is used to supply power to the acoustic detection module) and improving the service life of the device.

In some embodiments, the acoustic detection module comprises a Sigma-Delta (I-A) modulator, the Σ-Δ modulator being configured to perform signal modulation on the acoustic signal using pulse density modulation to convert same from an analog signal format to a pulse density modulated digital signal format.

In some embodiments, the communication module is configured to be communicatively coupled to a communication device at the site, so as to be communicatively coupled to the remote device via the communication device.

According to another aspect of the present disclosure, there is further provided a method for monitoring partial discharges of an electrical device within a site by using a partial discharge detection apparatus. The method comprises disposing at least a part of the partial discharge detection apparatus within the site and facing same toward the electrical device; receiving, by the partial discharge detection apparatus, a sound wave generated by the electrical device and generating a corresponding acoustic signal; determining, by the partial discharge detection apparatus on the basis of the acoustic signal, whether a partial discharge has occurred in the electrical device; generating, by the partial discharge detection apparatus, an alarm notification in response to determining that a partial discharge has occurred in the electrical device; and sending out, by the partial discharge detection apparatus, the alarm notification.

According to still another aspect of the present disclosure, there is further provided a partial discharge detection apparatus. The partial discharge detection apparatus comprises an acoustic detection module and a communication module. The acoustic detection module is disposed within a high-voltage site and configured to face an electrical device to detect a sound wave generated by the electrical device and generate a corresponding acoustic signal, and the communication module is coupled to the acoustic detection module to receive the acoustic signal, and configured to be communicatively coupled to a remote device to send the acoustic signal to the remote device, thereby allowing the remote device to determine, on the basis of the acoustic signal, whether a partial discharge has occurred in the electrical device. The partial discharge detection apparatus may choose to send the acoustic signal to a remote device instead of processing it locally, which is advantageous for reducing the complexity and cost of the partial discharge detection apparatus.

The foregoing is a summary of aspects of the present disclosure where simplification, generalization, and omitted details may exist. Therefore, it should be appreciated by those skilled in the art that this section is for exemplary illustration only, and not intended to limit the scope of the present disclosure by any means. This summary section is not intended to identify key features or essential features of the claimed subject matter, and is not intended to be used as a supplementary way to identify the scope of the claimed subject matter.

### BRIEF DESCRIPTION OF THE SEVERAL VIEWS OF THE DRAWINGS

Those skilled in the art will more fully and clearly understand the aforementioned and other features of the present disclosure through the detailed description made below with reference to the accompanying drawings and the appended claims. It can be understood that these accompanying drawings and detailed description merely describe several exemplary embodiments of the present disclosure and should not be considered limitations to the scope of the present application. The present disclosure will be described with more clarity and in more detail with reference to the accompanying drawings.

FIG. 1 is a schematic structural view of a partial discharge detection apparatus according to an embodiment of the present application.

FIG. 2 is a schematic structural view of a partial discharge detection apparatus according to another embodiment of the present application.

FIG. 3 is a schematic structural view of a partial discharge detection apparatus according to another embodiment of the present application.

FIG. 4 is a flowchart of a method for monitoring partial discharges of an electrical device within a site by using a partial discharge detection apparatus according to an embodiment of the present application.

FIG. 5 is a flowchart of a method for monitoring partial discharges of an electrical device within a site by using a partial discharge detection apparatus according to an embodiment of the present application.

### DETAILED DESCRIPTION

The following detailed description is made with reference to the accompanying drawings constituting a part of the specification. Unless otherwise specified in the context, similar symbols usually represent similar components in the accompanying drawings. The illustrative embodiments described in the detailed description, the accompanying drawings, and the claims are not limiting. Other embodiments may be adopted, or other modifications may be made without departing from the spirit or scope of the subject matter of the present disclosure. It can be understood that the various aspects of the present disclosure generally described in the present disclosure and graphically presented in the accompanying drawings may be arranged, replaced, combined, and designed in many different configurations, and these different configurations explicitly constitute a part of the present application.

Wind farms or solar power plants are generally built on open water surfaces or in rugged mountainous areas, and due to the complex and harsh working environment in the field, the aging of devices is accelerated, and compact substations are more prone to partial discharge. At present, a manual inspection system is usually used in wind farms or solar power plants to observe and determine electrical device failures, including partial discharges. In the inspection system, an inspection period is generally set, once a month or once every two months. If a device failure that needs to be handled is not found in the current inspection operation, the next time inspection will be performed will be after one inspection period, and a partial discharge cannot be promptly detected. In addition, an early partial discharge may have no obvious signs, and has little impact on the normal operation of the electrical device, which makes it difficult for inspection staff to discover. Therefore, the current inspection system has a monitoring empty window period and is a passive maintenance method, and the inspection staff cannot promptly know the operating conditions of the electrical device. This manner of inspection may result in early partial discharges not being promptly found, instead only being able to be found after significant failure of the electrical device, increasing the risk of operation and maintenance costs of the device.

According to an aspect of the present disclosure, a partial discharge detection apparatus may be placed in, e.g., a high-voltage space of a compact substation of a wind farm or a solar power plant, may use an acoustic sensor to detect partial discharges, and can continuously detect partial discharges of various devices within the site and can promptly send an alarm to a remote device when a partial discharge is detected. This detection may be automatically performed at any time as needed, without relying on maintenance personnel to go to the site for testing. Further, the partial discharge detection apparatus may find the partial discharge by way of using the acoustic sensor to detect a sound wave, i.e., a non-electrical signal, which can effectively avoid electromagnetic interference in the high-voltage space and discover an early partial discharge of the electrical device. According to some embodiments of the present disclosure, the partial discharge detection apparatus can actively detect and identify a partial discharge of a device inside a compact substation, and continuously collect data of the partial discharge, thereby monitoring and predicting a potential abnormal state of the device, reducing the operation risk of the device, and achieving predictive maintenance of the compact substation.

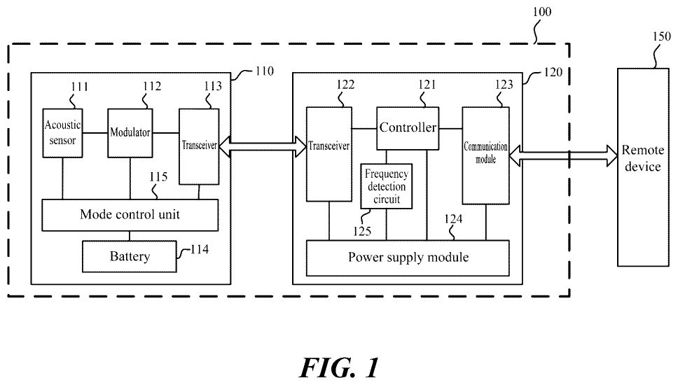

With reference to FIG. 1, a schematic structural view of a partial discharge detection apparatus 100 in an embodiment of the present disclosure is shown. Specifically, the partial discharge detection apparatus 100 includes an acoustic detection module 110 and a control module 120. The acoustic detection module 110 is disposed within a monitored site and is configured to face a monitored electrical device to detect a sound wave generated by the electrical device and generate a corresponding acoustic signal, such as an ultrasonic signal generated by a partial discharge. The control module 120 is coupled to the acoustic detection module 110 to receive the acoustic signal and determines, on the basis of the acoustic signal, whether a partial discharge has occurred in the monitored electrical device. Optionally, the control module 120 can also generate, when it is determined that a partial discharge has occurred in the electrical device, an alarm notification and send the alarm notification to a remote device 150. Specifically, the control module 120 may be implemented to include a signal processing module (not separately shown in the figure) and a communication module, wherein the communication module is primarily responsible for communication with the remote device 150, and the signal processing module is responsible for other signal processing and control, especially the processing with the front-end acoustic detection module 110.

In some embodiments, the monitored electrical device may be an electrical device, e.g., a high-voltage cable, a high-voltage switchgear, a transformer, an instrument transformer, a vacuum switch, a rotary isolator switch, a spring-operated mechanism, or the like, in a high-voltage chamber or a transformer chamber of a pad-mounted transformer used in a wind farm or a solar power plant. In some other embodiments, the partial discharge detection apparatus 100 may also be used to monitor transformers in various power distribution networks, high-voltage electrical devices in power transmission lines, etc., which are often at risk of partial discharge due to factors such as aging, moisture, out-of-specification installation, etc.

In the example of FIG. 1, the acoustic detection module 110 includes one or more acoustic sensors 111, a modulator 112, and a transceiver 113. The acoustic sensor 111 is used to detect a sound wave, in particular an ultrasonic signal, generated by the monitored electrical device during a partial discharge. For example, the monitored electrical device may generate an electric arc, an electric trace, a corona, etc., during the partial discharge, ionizing the air around it and generating an ultrasonic wave. Accordingly, the acoustic sensor 111 may detect the ultrasonic wave and convert it into an analog quantity represented by a voltage or a current. Next, the modulator 112 receives an acoustic signal generated by the acoustic sensor 111, that is, the voltage or current analog quantity, converts it into a digital signal for modulation, and transmits same to the transceiver 113. The transceiver 113 then sends the modulated digital signal to the control module 120 for processing.

In some embodiments, the acoustic sensor 111 is a non-contact resonant sensor. For example, the acoustic sensor 111 is a resonant sensor using a piezoelectric ceramic material, and utilizes the piezoelectric effect of the piezoelectric ceramic and deforms under the mechanical stress of a sound wave generated by a partial discharge to generate a corresponding electrical signal. In some other embodiments, the acoustic sensor 111 may also be a capacitive acoustic sensor, a moving iron or moving coil acoustic sensor, a micro-electromechanical system (MEMS) ultrasonic sensor manufactured using micromachining technology, or the like. The non-contact acoustic sensor 111 or the acoustic detection module 110 including same may be mounted within a monitored site (e.g., a wall or a surface of a device) by way of an attachment such as an adhesive attachment or a magnetic attachment, or by way of a fastener such as a screw, and faces the monitored electrical device. Using, as an example, a sensing angle range of the acoustic sensor 111 of 60° and a sensing distance of 3 m, at least the whole of the monitored electrical device or a part thereof in which a partial discharge is likely to occur should be within the above-described sensing angle range and sensing distance of the acoustic sensor 111.

In some embodiments, the operating frequency of the acoustic sensor 111 is 2 kHz to 200 kHz. Preferably, the acoustic sensor 111 may monitor ultrasonic waves having a frequency between 30 kHz and 50 kHz. In some embodiments, the operating frequency of the acoustic sensor 111 may be adjusted or selected, for example, an operator may select a frequency band of 5 kHz to 20 kHz, or 30 kHz to 50 kHz, and a corresponding center frequency within the range of 2 kHz to 200 kHz according to the nature of the monitored electrical device and/or the type of partial discharge to more accurately detect the sound wave associated with the partial discharge.

It can be understood that the type, sensing distance and angle range, and operating frequency parameters of the acoustic sensor 111 as described above are provided by way of example only, and are not limiting. In other embodiments, the acoustic sensor may also have other types and/or parameters. For example, the acoustic sensor may also be a contact sensor that may be attached to a housing of the monitored electrical device by way of an ultrasonic coupling agent to detect sound waves propagating through the housing of the monitored electrical device.

Continuing to describe by using, as an example, monitoring the electrical device of the pad-mounted transformer, there may be a plurality of electrical devices to be monitored in the pad-mounted transformer, or there may be a plurality of partial discharge risk points to be monitored in one electrical device. To monitor the plurality of electrical devices or the plurality of risk points, the acoustic sensor 111 in the acoustic detection module 110 may have different configurations.

In some embodiments, the acoustic detection module 110 may include a plurality of acoustic sensors 111. The plurality of acoustic sensors 111 are disposed at different positions of the cabinet of the pad-mounted transformer, and respectively face a plurality of different electrical devices or different parts of the same electrical device to respectively detect sound waves generated by the corresponding electrical devices or parts. In some embodiments, each acoustic sensor 111 may be uniquely identified, e.g., with a corresponding sensor identifier, so that an acoustic signal generated thereby may also be provided to a subsequent module along with the identifier.

In other embodiments, the acoustic detection module 110 includes at least one or more acoustic sensors 111. The one or more acoustic sensors 111 are mounted on a rotatable base to be rotated by the rotatable base to face a plurality of different electrical devices or different parts of the same electrical device, thereby separately detecting, from different directions, sound waves generated by corresponding electrical devices or parts and generating corresponding acoustic signals. It can be understood that the use of the rotatable base increases the detection range, particularly the angle range, of the acoustic sensor 111, so that it is possible to reduce the number of acoustic sensors 111 required in the same site. Considering that partial discharges generally develop slowly, it takes, for example, several tens of minutes, several hours, or more from the occurrence of a detectable sound wave to the occurrence of a substantial abnormality (e.g., an abnormality corresponding to a fault such as a short circuit or an open circuit), and thus the rotatable base may correspondingly rotate stepwise at a slow speed (e.g., one revolution every 10 minutes) and does not need to always be in a fast rotation state, which may reduce the overall power consumption of the acoustic detection module 110.

In other embodiments, the acoustic detection module 110 includes a plurality of acoustic sensors 111. The plurality of acoustic sensors 111 are mounted within the same housing, but directed toward a plurality of different electrical devices or different parts of the same electrical device. By way of activating the plurality of acoustic sensors 111 at the same time, it is possible to detect, from different directions, sound waves generated by the corresponding electrical devices or parts and generate corresponding acoustic signals for subsequent detection and discovery of partial discharges.

In yet other embodiments, the acoustic detection module 110 includes a sensor array having a plurality of acoustic sensors 111. The sensor array may be a MEMS sensor array including, for example, 32 to 256 or more acoustic sensor elements. The sensor array may be configured to use a beamforming technique to detect sound waves generated by the plurality of electrical devices and generate corresponding acoustic signals. The beamforming technique can combine signals detected by the plurality of acoustic sensors in the sensor array such that signals from sound sources at certain angles are subject to constructive interference while other signals are subject to destructive interference. After acquiring the combined acoustic signal, the control module 120 can analyze the information to determine a part of the electrical device in which the partial discharge has occurred.

Further, in some embodiments, an image sensor may also be disposed within the pad-mounted transformer or integrated within the acoustic detection module 110. The image sensor may acquire image information of the interior of the pad-mounted transformer, particularly of the monitored electrical device, and the partial discharge position determined by the control module 120 may be subsequently displayed in superposition with the image acquired by the image sensor to more clearly indicate the partial discharge position. In some embodiments, the image sensor may remain in an off state by default and only be turned on after the acoustic detection module 110 detects an abnormal acoustic signal associated with a possible partial discharge to coordinate the detection of the sound wave.

With reference to FIG. 1, the acoustic detection module 110 further includes a modulator 112, which is coupled to the acoustic sensor 111 and receives the acoustic signal from the acoustic sensor 111. The modulator 112 can convert the acoustic signal from an analog quantity to a digital quantity and modulate the digital quantity onto a high frequency carrier for transmission.

In some embodiments, the modulator 112 is a Sigma-Delta (Σ-Δ) modulator, which can perform signal modulation on the acoustic signal using pulse density modulation (PDM) to convert same from an analog signal format to a pulse density modulated digital signal format. The Σ-Δ modulator has a simple circuit structure, and in the process of converting an analog signal into a digital signal, a conversion value of each analog sample is a relative value of the previous analog sample, which has continuity, and is closer to a characteristic of an original sound. Therefore, the Σ-Δ modulator has broad applications in the field of audio conversion. The specific structure of the Σ-Δ modulator is not described in detail in the present disclosure, and reference may be made to the relevant description in the prior art. The digital output after analog-to-digital conversion of the analog signal by the Σ-Δ modulator is expressed in terms of timing as a sequence of digital signals “0” and “1” of which the density varies with an increase or decrease in the input signal level, which is pulse density modulation. Since, in PDM, a signal is encoded as a series of pulses of equal width consisting of digital signals “0” and “1”, and the amplitude variation of the signal is represented by the density of the pulses, it has a higher anti-interference ability and is more suitable for high-voltage environments with severe electromagnetic interference. It should be understood that in other embodiments, other types of digital-to-analog converters and modulators may be used, and the present disclosure does not impose any limitations in this regard.

With continued reference to FIG. 1, in the example of FIG. 1, the acoustic detection module 110 and the control module 120 of the partial discharge detection apparatus 100 are two separately packaged components. For example, they may be disposed in different housings or placed on different substrates, and communicatively coupled but electrically isolated from each other. The two separately packaged components may not need to be placed in the same housing. As such, a user may respectively place the acoustic detection module 110 and the control module 120 at desired locations, e.g., within different sites, as desired or according to other considerations.

Specifically, the transceiver 113 is included in the acoustic detection module 110 and, correspondingly, another transceiver 122 is included in the control module 120. The two transceivers 113 and 122 may be coupled by way of a communication cable for pair-wise communication, but may be electrically isolated from each other, that is, there is no direct connection of a wired conductive line. In some embodiments, two-way communication may be implemented between the two transceivers 113 and 122, but optionally, only one-way communication may be implemented, that is, the transceiver 113 sends a signal to the transceiver 122. The transceiver 113 receives the modulated acoustic signal from the modulator 112 and sends same to the transceiver 122 by way of the communication cable. In an example, the transceiver 113 in the acoustic detection module 110 and the transceiver 122 in the control module 120 are both fiber optic transceivers that are coupled by way of a fiber optic cable communication cable but are electrically isolated from each other. For example, the acoustic detection module 110 is mounted or disposed inside a high-voltage site, while the control module 120 is disposed outside the high-voltage site. The fiber optic transceivers in the acoustic detection module 110 and the control module 120 are coupled by way of the fiber optic cable. Since both the acoustic detection module 110 and the control module 120 are in different housings and coupled by way of an optical fiber, they are electrically isolated from each other. As such, even if the acoustic detection module 110 located in the high-voltage space is electrically damaged, the relevant electrical signal is not conducted to the control module 120 via a conductive line, thereby ensuring the electrical safety of the control module 120.

It can be understood that the above-described fiber optic transceivers and fiber optic cable are merely non-limiting examples of the present disclosure, and in some other embodiments, a wireless connection (e.g., Bluetooth, infrared, a wireless local area network, a cellular network) may also be used to couple the transceivers in the acoustic detection module 110 and the control module 120 and implement the transmission of the acoustic signal.

As shown in FIG. 1, the control module 120 further includes a controller 121. The controller 121 receives, from the transceiver 122, the acoustic signal detected by the acoustic detection module 110, and determines, on the basis of the acoustic signal, whether a partial discharge has occurred in the monitored electrical device. For example, when a pulse having an abnormally increased amplitude (for example, two or more times a predetermined amplitude upper limit or two or more times an average amplitude in a normal case) is included in the acoustic signal, or when a spectral distribution or a waveform of a predetermined form (representing an abnormal form) is included in the acoustic signal, or when a spectral distribution or a waveform of a predetermined form (representing a normal form) is included in the acoustic signal, the control module 120 may determine that a partial discharge might have occurred in the electrical device. Those skilled in the art could recognize various suitable ways to analyze the acoustic signal and determine whether a partial discharge has occurred. After determining that a partial discharge has occurred in the electrical device, the controller 121 may generate a corresponding alarm notification. It can be understood that, in some embodiments, the alarm notification may include an identifier of the control module 120 and/or the acoustic detection module 110 to allow devices and personnel receiving the alarm notification to more easily identify a high-voltage site where the partial discharge might have occurred or a specific electrical device therein or a part thereof.

In some embodiments, the controller 121 may include, for example, one or more application-specific integrated circuits (ASICs), digital signal processors (DSPs), digital signal processing (DSP) devices, programmable logic devices (PLDs), field-programmable gate arrays (FPGAs), controllers, micro-controllers, microprocessors, embedded systems on chips (SoCs), or other electronic elements. The controller 121 may be programmed to perform or implement the various operations or functions described herein.

For example, the controller 121 may be configured to generate a phase resolved partial discharge (PRPD) spectrum on the basis of the acoustic signal. Partial discharges are typically caused by a certain type of defect inside a high-voltage insulation system or on the surface thereof. Since these defects cannot insulate the voltage applied thereto, discharge occurs at these defects. As the voltage of the utility frequency of each cycle of a power system is applied to the defect, the defect is caused to discharge at a specific time and voltage amplitude, thereby exhibiting a voltage rise and fall with respect to the utility frequency, so that the partial discharge exhibits a regular change. The PRPD spectrum includes an X-axis describing a phase angle and a Y-axis describing the amplitude of a partial discharge event, thereby describing the partial discharge activity and its characteristics within one AC cycle (360°). The controller 121 may be further configured to perform feature extraction on the PRPD spectrum and evaluate the type and/or intensity of the partial discharge occurring in the monitored electrical device. For example, the controller 121 may be configured to determine whether the type of partial discharge is a corona discharge, an arc discharge, a surface discharge, or an air gap discharge, or to evaluate whether the monitored electrical device exhibits only an initial characteristic of a partial discharge or whether a severe partial discharge has occurred. The specific manner of generating the PRPD spectrum and the method for determining the type and/or intensity of the partial discharge are not described in detail in the present application.

It should be noted that, considering that the partial discharge phenomenon is closely related to the rise and fall of the voltage of the utility frequency, in some embodiments, as shown in FIG. 1, the control module 120 further includes a frequency detection circuit 125. The frequency detection circuit 125 is configured to detect operating frequency (i.e., utility frequency) information of the AC power supply of the power system and send the operating frequency information to the controller 121. The controller 121 can calculate the phase difference between the operating frequency and the frequency of the aforementioned acoustic signal, and determine, on the basis of phase difference information in combination with the characteristics of the acoustic signal, whether a partial discharge has occurred in the monitored electrical device, and type and/or intensity information of the partial discharge, with higher accuracy. For example, when there is no correspondence between the phase difference between the AC power supply and the acoustic signal and an abnormal acoustic signal, it can be considered that the abnormal acoustic signal is not generated due to a partial discharge (which, for example, generally occurs when the utility frequency voltage rises), and therefore, it can be determined that a partial discharge has not occurred, that is, the alarm notification is no longer generated.

The partial discharge detection apparatus 100 further includes a communication module 123 for communication between the partial discharge detection apparatus 100 and the outside. After the controller 121 determines that a partial discharge has occurred in the monitored electrical device and generates an alarm notification, the alarm notification may be sent to the remote device 150 by way of the communication module. The communication module 123 may also send, to the remote device 150, the evaluated type and/or intensity of the partial discharge, or other information. In the example of FIG. 1, the communication module 123 is integrated within the same housing of the control module 120. In some other embodiments, the communication module 123 may be disposed within a different housing than the control module 120.

In some embodiments, the communication module 123 may be any type of apparatus operable to communicate with another apparatus. The communication module 123 may be a transceiver, a modem, or the like. The communication module 123 may be configured to communicate using a suitable type of communication protocol. For example, the communication module 123 is coupled to the remote device 150 by way of a communication network, which may be an ad hoc network, an intranet, an extranet, a virtual private network (VPN), a local area network (LAN), a wireless local area network (WLAN), a wide area network (WAN), a wireless wide area network (WWAN), a metropolitan area network (MAN), a portion of the Internet, a portion of the public switched telephone network (PSTN), a cellular telephone network, a wireless network, a WiFi network, a WiMax network, or any other type of network, or any combination of two or more such networks. The remote device 150 may be operated by maintenance personnel or other personnel of the monitored electrical device to perform corresponding handling after receiving the alarm notification transmitted by the communication module 123. The remote device 150 may be any type of computing device, for example, a laptop computer, a desktop computer, a smart phone, a tablet computer, a wearable computer (such as a smart watch or an augmented reality or virtual reality headset), or the like.

With continued reference to FIG. 1, as described previously, in this example, the acoustic detection module 110 and the control module 120 of the partial discharge detection apparatus 100 may be disposed in different housings. In a typical application scenario, the acoustic detection module 110 may be disposed in a high-voltage chamber of a pad-mounted transformer used in a wind farm or a solar power plant, and the control module 120 may be disposed in a relatively low-voltage transformer chamber of the pad-mounted transformer. Placing the control module 120 in a low-voltage environment instead of directly exposing same to a high-voltage site may reduce the risk of damage to the control module 120 due to partial discharge or more severe electrical failure. In some cases, since the high-voltage chamber of the pad-mounted transformer needs to be electrically isolated from the outside and there is no AC power supply available for external devices, the acoustic detection module 110 may also include a battery 114 for supplying power to the acoustic sensor 111, the modulator 112, and the transceiver 113. However, the AC power supply of the power system in the transformer chamber of the pad-mounted transformer can be used externally, and accordingly, the partial discharge detection apparatus 100 further includes a power supply module 124 which is electrically connected to the AC power supply of the power system. The power supply module 124 is configured to convert AC power of the power system into a voltage required for the controller 121, the transceiver 122, the communication module 123, the frequency detection circuit 125, and the like, and to supply power to same. For example, the power supply module 124 may be an AC-DC conversion circuit and have an interface or cable that may be coupled to an AC power supply. In some cases, the power supply module 124 may also optionally include a power storage module, such as a battery or a capacitor (e.g., a super-capacitor). In addition, since the frequency detection circuit 125 is coupled to the power supply module 124, the frequency detection circuit 125 can also acquire, from the power supply module 124, the operating frequency of the AC power supply of the power system.

As described above, the battery 114 supplies power to the acoustic detection module 110, and the power and the life of the battery 114 will become limiting factors in the performance life cycle of the partial discharge detection apparatus 100. This is because wind farms or solar power plants are generally built on open water surfaces or in rugged mountainous areas, and it will be more difficult to replace the battery 114 of the acoustic detection module 110 due to the complex and harsh working environment in the field. For this reason, the partial discharge detection apparatus 100 provides different operating modes to save energy consumption of the battery 114.

Specifically, as shown in FIG. 1, the acoustic detection module 110 may include a mode control unit 115. The mode control unit 115 is configured to receive an operating mode instruction from the controller 121 of the control module 120 via the transceiver 113 and the transceiver 122. The operating mode instruction may include a continuous detection mode instruction or an intermittent detection mode instruction. When the mode control unit 115 receives the continuous detection mode instruction, the mode control unit 115 can control the acoustic sensor 111 to detect, at a first detection frequency, the sound wave generated by the electrical device and generate a corresponding acoustic signal. When the mode control unit 115 receives the intermittent detection mode instruction, the mode control unit 115 can control the acoustic sensor 111 to detect, at a second detection frequency, the sound wave generated by the electrical device and generate a corresponding acoustic signal, wherein the first detection frequency is higher than the second detection frequency. For example, the controller 121 may generate the intermittent detection mode instruction after the partial discharge detection apparatus 100 is powered on, thereby instructing the partial discharge detection apparatus 100 to perform intermittent detection, for example, once every 10 minutes, 20 minutes, or 30 minutes. After the controller 121 receives an abnormal acoustic signal, the controller 121 may generate, in response to the abnormal signal, a continuous detection mode instruction instructing the partial discharge detection apparatus 100 to perform continuous detection. Additionally, when the acoustic detection module 110 is in the continuous detection mode, and no partial discharge of the electrical device has been found within a predetermined operation time (for example, within 5 minutes or 10 minutes), the controller 121 may generate an intermittent detection mode instruction instructing the partial discharge detection apparatus 100 to perform intermittent detection. The controller 121 may send the continuous detection mode instruction or the intermittent detection mode instruction to the mode control unit 115 via the transceiver 122 and the transceiver 113. In some embodiments, when the acoustic sensor 111 is in a different detection mode, all, or at least some, of the other modules of the partial discharge detection apparatus 100 may also be correspondingly in a different operating mode, for example, similarly be in an intermittent operating mode in cooperation with the acoustic sensor 111 in the intermittent detection mode, thereby reducing power consumption.

In some other embodiments, the mode control unit 115 may also generate the operating mode instruction in other manners. For example, the mode control unit 115 may generate the continuous detection mode instruction when the amount of power of the battery 114 is higher than a predetermined lower limit, and generate the gap detection mode instruction when the amount of power of the battery 114 is lower than the predetermined lower limit. That is, the partial discharge detection apparatus 100 can reduce the detection frequency when the amount of power of the battery is insufficient, thereby reducing power consumption. Correspondingly, the partial discharge detection apparatus 100 may also send a corresponding prompt signal to an external device when the amount of power of the battery is insufficient, so as to prompt the operator to change the battery on site.

In some embodiments, the mode control unit 115 may include a timer by way of which the detection frequency of the acoustic sensor 111 is controlled. For example, the mode control unit 115 may be coupled between the battery 114 and the acoustic sensor 111, the modulator 112, and the transceiver 113, and when the mode control unit 115 receives the continuous detection mode instruction, the mode control unit 115 controls the battery 114 to supply power to the acoustic sensor 111, the modulator 112, and the transceiver 113 at a specific interval (e.g., 10 minutes or 20 minutes), and cuts off the power supply to same after the acoustic sensor 111 completes the detection of the sound wave of the electrical device and transmits same to the control module 120. Correspondingly, when the mode control unit 115 receives the intermittent detection mode instruction, the mode control unit 115 controls the battery 114 to supply power to the acoustic sensor 111, the modulator 112, and the transceiver 113 at a longer time interval (for example, 1 hour or 2 hours), and cuts off the power supply to same after the acoustic sensor 111 completes the detection of the sound wave of the power device and transmits same to the control module 120. On the basis of the foregoing, the acoustic detection module 110 detects the sound wave of the electrical device at a higher frequency only when the electrical device is powered on for the first time or when there is a risk of partial discharge, and at a lower operating frequency for the rest of the time, which can significantly reduce the power consumption of the battery 114 and improve the service life thereof. Compared with the long inspection period of manual inspection, this intermittent detection mechanism still enables partial discharges to be promptly found, while taking into account the generally slow progression time of partial discharges.

In the above embodiment, the partial discharge detection apparatus 100 has been described with reference to an example in which the battery is used to supply power to the acoustic detection module 110 and the AC power supply of the power system is used to supply power to the control module 120, but the present disclosure is not limited thereto. In other embodiments, the AC power supply of the power system may also be used to supply power to the acoustic detection module, and the battery may also be used to supply power to the control module.

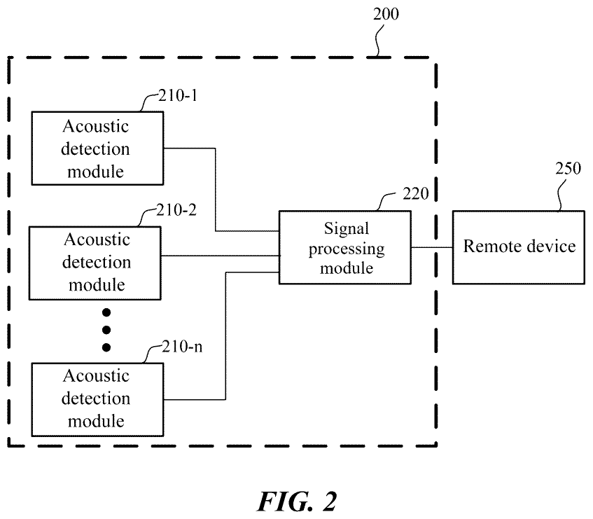

With reference to FIG. 2, a schematic structural view of a partial discharge detection apparatus 200 in another embodiment of the present disclosure is shown. As shown in FIG. 2, the partial discharge detection apparatus 200 includes a plurality of acoustic detection modules 210-1, 210-2, . . . , and 210-n, and a control module 220 separately coupled to the plurality of acoustic detection modules 210-1, 210-2, . . . , and 210-n. The plurality of acoustic detection modules 210-1, 210-2, . . . , and 210-n may each have a structure and configuration the same as or similar to those of the acoustic detection module 110 described above with reference to FIG. 1, the control module 220 may have a structure and configuration the same as or similar to those of the control module 120 described above with reference to FIG. 1, and details will not be described here.

In the partial discharge detection apparatus 200 shown in FIG. 2, when there are a plurality of electrical devices to be monitored (for example, a plurality of pad-mounted transformers of a wind farm or a solar power plant) in a high-voltage space, or there are a plurality of partial discharge risk points to be monitored on one electrical device, the plurality of acoustic sensors 210-1, 210-2, . . . , and 210-n may be respectively disposed at different positions in the high-voltage space and respectively face the plurality of different electrical devices or different parts of the same electrical device, so as to respectively detect sound waves generated by the corresponding electrical devices or parts. The acoustic signals generated by the plurality of acoustic sensors 210-1, 210-2, . . . and 210-n detecting the sound waves may be collectively transmitted to the same control module 220 for processing. The control module 220 determines, on the basis of the acoustic signals, whether a partial discharge has occurred in the plurality of different electrical devices or in the different parts of the same electrical device; generates an alarm notification in response to determining that a partial discharge has occurred in an electrical device; and transmits the alarm notification via a communication module to a remote device 250 coupled thereto.

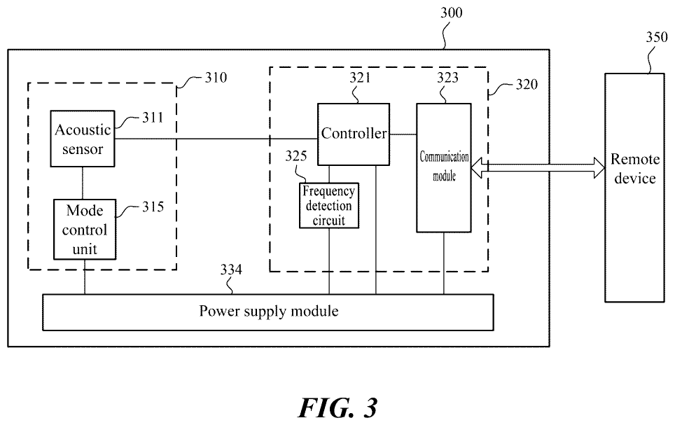

With reference to FIG. 3, a schematic structural view of a partial discharge detection apparatus 300 in another embodiment of the present disclosure is shown. As shown in FIG. 3, the partial discharge detection apparatus 300 includes an acoustic detection module 310 and a control module 320. Similar to the partial discharge detection apparatus 100 described above with reference to FIG. 1, the acoustic detection module 310 can detect a sound wave generated by an electrical device in a high-voltage site and generate a corresponding acoustic signal, and the control module 320 is coupled to the acoustic detection module 310 to receive the acoustic signal, and is configured to determine, on the basis of the acoustic signal, whether a partial discharge has occurred in the electrical device, and to generate an alarm notification in response to determining that a partial discharge has occurred in the electrical device. The control module 320 is further coupled to a remote device 350 by way of a communication module therein to send the alarm notification to the remote device 350.

The difference from the partial discharge detection apparatus 100 described above with reference to FIG. 1 is that the acoustic detection module 310 and the control module 320 of the partial discharge detection apparatus 300 shown in FIG. 3 are disposed in the same housing, and therefore, the acoustic detection module 310 does not need a modulator and a transceiver, but includes only an acoustic sensor 311 and a mode control unit 315. In addition, the control module 320 does not need a transceiver, and only includes a controller 321, a communication module 323, and a frequency detection circuit 325. In addition, the acoustic detection module 310 and the control module 320 may share a power supply module 334, and there is no need to separately provide power supply modules. The power supply module 334 may be a battery or an AC power supply coupled to a power system. With respect to the functions and configurations of the acoustic sensor 311, the mode control unit 315, the controller 321, the communication module 323, and the frequency detection circuit 325, reference may be made to the acoustic sensor 111, the mode control unit 115, the controller 121, the communication module 123, and the frequency detection circuit 125 described in FIG. 1, respectively, and details will not be described here.

It can be understood that the partial discharge detection apparatus 300 shown in FIG. 3 is suitable for the case where a point of interest of a partial discharge to be monitored is located in a single high-voltage space and can be covered by one acoustic detection module 310, the arrangement of which is simpler.

It should be noted that, in all of the above embodiments, the control module of the partial discharge detection apparatus has been described using an example in which the control module is suitable for being disposed at or near the monitored site, that is, it is a “local” module of the monitored site. However, in some other embodiments, some or all of the functions and modules of the control module may be disposed in a remote device, such as a server. Thus, the acoustic detection module may also send to the remote device an acoustic signal generated by its detection, and a predetermined program or method is performed by the remote device to determine, on the basis of the received acoustic signal, whether a partial discharge has occurred in the electrical device, and to generate an alarm notification in response to determining that a partial discharge has occurred. In still other embodiments, after determining, on the basis of the acoustic signal, that a partial discharge has occurred in the electrical device, and generating the alarm signal, the control module of the partial discharge detection apparatus not only sends the alarm signal to the remote device, but also sends the acoustic signal to the remote device. Thus, the remote device can, after receiving the alarm signal, perform evaluation and/or determination on the acoustic signal on the basis of a more comprehensive analysis method and/or historical data to obtain more accurate and comprehensive information about the partial discharge. For more functions and details of the remote device, reference may be made to the description about the control module in the embodiments shown in FIGS. 1, 2, and 3, and details will not be described here. It can be understood that in such a case, the partial discharge detection apparatus may include a communication module that may employ any suitable communication hardware, software, and protocol to couple to the remote device (e.g., directly communicatively couple to the remote device, or indirectly couple to the remote device by way of a communication device associated with the monitored site) and send the acoustic signal generated by the acoustic detection module to the remote device.

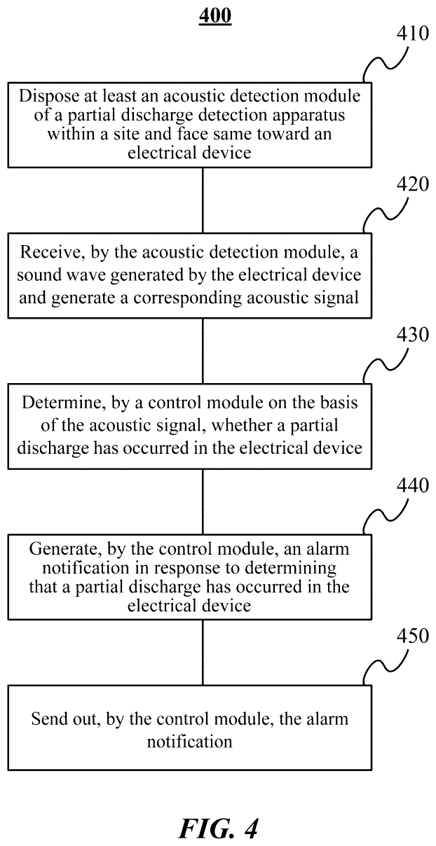

With reference to FIG. 4, according to another aspect of the present disclosure, there is also provided a method 400 for monitoring partial discharges of an electrical device within a site by using the partial discharge detection apparatus described above. The partial discharge detection apparatus includes an acoustic detection module and a control module that are communicatively coupled but electrically isolated from each other.

As shown in FIG. 4, at 410, at least a part of the partial discharge detection apparatus, for example, the acoustic detection module, is disposed within a high-voltage site and faces the monitored electrical device. Next, at 420, a sound wave generated by the electrical device is received by the acoustic detection module and a corresponding acoustic signal is generated. Next, at 430, it is determined by the control module, on the basis of the acoustic signal, whether a partial discharge has occurred in the electrical device. Next, at 440, an alarm notification is generated by the control module in response to determining that a partial discharge has occurred in the electrical device. Then, at 450, the alarm notification is sent out by the control module.

In some embodiments, the acoustic detection module and the control module of the partial discharge detection apparatus are coupled to each other by way of a communication cable, and disposing the acoustic detection module of the partial discharge detection apparatus within the high-voltage site and facing same toward the electrical device at 410 further includes: disposing the acoustic detection module and the control module inside and outside the site, respectively, and extending the communication cable between the inside of the site and the outside of the site.

In some embodiments, the method 400 further includes evaluating, by the control module on the basis of the acoustic signal, a type and/or intensity of the partial discharge occurring in the electrical device, and sending outwards, by the control module, the evaluated type and/or intensity of the partial discharge.

In some embodiments, the method 400 further includes coupling the partial discharge detection apparatus to an AC power supply supplying power to the electrical device within the high-voltage site; detecting, by the partial discharge detection apparatus, operating frequency information of the AC power supply; and determining, by the control module on the basis of the acoustic signal and the operating frequency information, whether a partial discharge has occurred in the electrical device.

In some embodiments, the method 400 further includes generating, by the control module, an operating mode instruction, wherein the operating mode instruction includes a continuous detection mode instruction or an intermittent detection mode instruction, and detecting, by the acoustic detection module at a first detection frequency and in response to the continuous detection mode instruction, the sound wave generated by the electrical device, or detecting, by the acoustic detection module at a second detection frequency and in response to the intermittent detection mode instruction, the sound wave generated by the electrical device, wherein the first detection frequency is higher than the second detection frequency. In some embodiments, the step of generating, by the control module, the operating mode instruction further includes generating, by the control module, the intermittent detection mode instruction after the partial discharge detection apparatus is powered on. In some embodiments, the step of generating, by the control module, the operating mode instruction further includes generating, by the control module, the continuous detection mode instruction in response to the acoustic detection module detecting an abnormal sound wave. In some embodiments, the step of generating, by the control module, the operating mode instruction further includes when the acoustic detection module is in the continuous detection mode and no partial discharge of the electrical device has been found within a predetermined operating time, generating, by the control module, the intermittent detection mode instruction.

Additionally, the present disclosure further provides another method 500 for monitoring partial discharges of an electrical device within a site by using a partial discharge detection apparatus. In this embodiment, an acoustic signal may not be processed locally, or may be partially processed locally, and the acoustic signal may also be sent to a remote device for evaluation and/or determination.

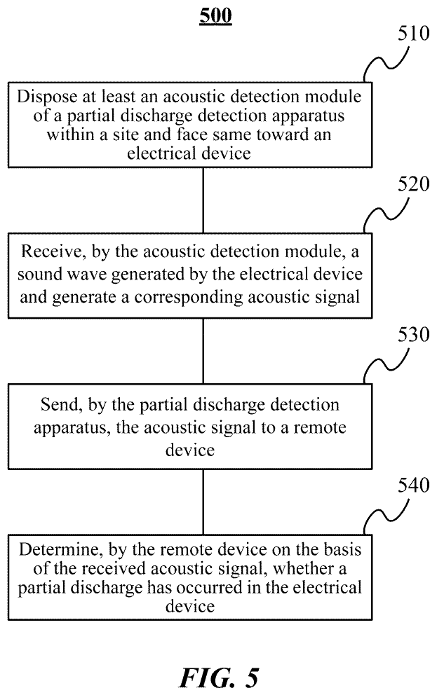

As shown in FIG. 5, at 510, at least an acoustic detection module of the partial discharge detection apparatus is disposed within a high-voltage site and faces the monitored electrical device. Next, at 520, a sound wave generated by the electrical device is received by the acoustic detection module and a corresponding acoustic signal is generated. Next, at 530, the acoustic signal is sent by the partial discharge detection apparatus to a remote device. Then, at 540, it is determined by the remote device, on the basis of the received acoustic signal, whether a partial discharge has occurred in the electrical device.

In some embodiments, the partial discharge detection apparatus may not have a control module that analyzes the acoustic signal. Then, at 530, the partial discharge detection apparatus simply sends the acoustic signal to the remote device, and at 540, the remote device determines, on the basis of the received acoustic signal, whether a partial discharge has occurred in the electrical device, and generates an alarm notification in response to determining that a partial discharge has occurred.

In some embodiments, the partial discharge detection apparatus may include a control module that analyzes the acoustic signal. Then, after 520, the control module of the partial discharge detection apparatus can determine, on the basis of the acoustic signal, whether a partial discharge has occurred in the electrical device, and generate an alarm notification in response to determining that a partial discharge has occurred. At 530, the partial discharge detection apparatus sends both the alarm signal and the acoustic signal to the remote device. At 540, after receiving the alarm signal, the remote device can evaluate the acoustic signal on the basis of a more comprehensive analysis method and/or historical data to obtain more accurate and comprehensive information about the partial discharge.

It can be seen that, according to different embodiments of the present disclosure, the acoustic sensor of the partial discharge detection apparatus detects the sound wave instead of an electrical signal, which can effectively avoid electromagnetic interference in the high-voltage space and discover an early partial discharge of the electrical device. Further, by way of data continuously collected from the partial discharge detection apparatus, the partial discharge can be actively detected and identified, and the future potential state of the device can be predicted, thereby reducing the risk, and predictive maintenance of high-voltage devices such as compact substations is achieved.

In view of the foregoing disclosure, various examples of the apparatus and method for monitoring partial discharges of an electrical device within a site may include the following feature: an acoustic detection module is disposed within the site and configured to face the electrical device to detect a sound wave generated by the electrical device and generate a corresponding acoustic signal.

Optionally, in some examples, the apparatus and method may include any one of or combination of the following features: a control module is coupled to the acoustic detection module to receive the acoustic signal; the control module is configured to determine, on the basis of the acoustic signal, whether a partial discharge has occurred in the electrical device; and the acoustic detection module and the control module are communicatively coupled but electrically isolated from each other.

Optionally, in some examples, the apparatus and method may include any one of or combination of the following features: a communication module is coupled to the acoustic detection module to receive the acoustic signal; and the communication module is configured to be communicatively coupled to a remote device to send the acoustic signal to the remote device, thereby allowing the remote device to determine, on the basis of the acoustic signal, whether a partial discharge has occurred in the electrical device.

Optionally, in some examples, the apparatus and method may include one or more of the following features: the acoustic detection module and the control module are configured to be disposed inside and outside the site, respectively; and the acoustic detection module and the control module are coupled to each other by way of a communication cable, and the communication cable is configured to extend between the inside of the site and the outside of the site to couple the acoustic detection module and the control module.

Optionally, in some examples, the apparatus and method may include the following feature: the communication cable includes a fiber optic cable.

Optionally, in some examples, the apparatus and method may include one or more of the following features: the acoustic detection module and the control module are two separately packaged components; and the acoustic detection module and the control module are respectively disposed inside and outside the site by way of respective attachments or fasteners.

Optionally, in some examples, the apparatus and method may include the following feature: the site described above is a high-voltage chamber or a transformer chamber of a pad-mounted transformer.

Optionally, in some examples, the apparatus and method may include the following feature: the control module is configured to generate an alarm notification in response to determining that a partial discharge has occurred in the electrical device.

Optionally, in some examples, the apparatus and method may include the following feature: the control module is configured to send the alarm notification to the remote device.

Optionally, in some examples, the apparatus and method may include one or more of the following features: the control module includes a signal processing module; the signal processing module is coupled to the acoustic detection module to receive the acoustic signal; the signal processing module is configured to determine, on the basis of the acoustic signal, whether a partial discharge has occurred in the electrical device; the signal processing module generates an alarm notification in response to determining that a partial discharge has occurred in the electrical device; the control module includes a communication module; the communication module is coupled to the signal processing module to receive the alarm notification; and the communication module is communicatively coupled to the remote device to send the alarm notification to the remote device.

Optionally, in some examples, the apparatus and method may include one or more of the following features: the control module is configured to evaluate, on the basis of the acoustic signal, a type and/or intensity of the partial discharge occurring in the electrical device; and the control module is configured to send the evaluated type and/or intensity of the partial discharge to the remote device via the communication module.

Optionally, in some examples, the apparatus and method may include the following feature: the partial discharge detection apparatus further includes a battery configured to supply power to the acoustic detection module.

Optionally, in some examples, the apparatus and method may include the following feature: the partial discharge detection apparatus further includes a power supply module configured to supply power to the control module.

Optionally, in some examples, the apparatus and method may include the following feature: the power supply module is configured to be coupled to an AC power supply used for supplying power to the electrical device within the site, so as to receive power from the AC power supply to supply power to the control module.

Optionally, in some examples, the apparatus and method may include one or more of the following features: the control module includes a frequency detection circuit; the frequency detection circuit is configured to detect operating frequency information of the AC power supply; and the control module is configured to determine, on the basis of the acoustic signal and the operating frequency information, whether a partial discharge has occurred in the electrical device.

Optionally, in some examples, the apparatus and method may include one or more of the following features: the acoustic detection module includes a plurality of acoustic sensors; and the plurality of acoustic sensors are disposed to respectively face different parts of the electrical device to respectively detect sound waves generated by the electrical device.

Optionally, in some examples, the apparatus and method may include one or more of the following features: the acoustic detection module includes at least one acoustic sensor; and the at least one acoustic sensor is mounted on a rotatable base to be rotated by the rotatable base to face different parts of the electrical device, thereby separately detecting, from different directions, the sound wave generated by the electrical device.

Optionally, in some examples, the apparatus and method may include one or more of the following features: the acoustic detection module includes a sensor array having a plurality of acoustic sensors; the sensor array is configured to use a beamforming technique to detect the sound wave generated by the electrical device; and the control module is configured to determine, on the basis of the acoustic signal corresponding to the sound wave detected using the beamforming technique, a part of the electrical device where the partial discharge has occurred.

Optionally, in some examples, the apparatus and method may include one or more of the following features: the acoustic detection module is configured to receive an operating mode instruction from the control module; the operating mode instruction includes a continuous detection mode instruction or an intermittent detection mode instruction; the acoustic detection module is configured to detect, at a first detection frequency and in response to receiving the continuous detection mode instruction, the sound wave generated by the electrical device; the acoustic detection module is configured to detect, at a second detection frequency and in response to receiving the intermittent detection mode instruction, the sound wave generated by the electrical device; and the first detection frequency is higher than the second detection frequency.

Optionally, in some examples, the apparatus and method may include one or more of the following features: the control module is configured to generate the intermittent detection mode instruction after the apparatus is powered on; and the control module is configured to send the intermittent detection mode instruction to the acoustic detection module.

Optionally, in some examples, the apparatus and method may include one or more of the following features: the control module is configured to generate the continuous detection mode instruction in response to receiving an abnormal acoustic signal; and the control module is configured to send the continuous detection mode instruction to the acoustic detection module.

Optionally, in some examples, the apparatus and method may include one or more of the following features: the control module is configured to, when the acoustic detection module is in the continuous detection mode and no partial discharge of the electrical device has been found within a predetermined operating time, generate the intermittent detection mode instruction; and the control module is configured to send the intermittent detection mode instruction to the acoustic detection module.

Optionally, in some examples, the apparatus and method may include one or more of the following features: the acoustic detection module includes a Σ-Δ modulator; and the Σ-Δ modulator is configured to perform signal modulation on the acoustic signal using pulse density modulation to convert same from an analog signal format to a pulse density modulated digital signal format.

Optionally, in some examples, the apparatus and method may include one or more of the following feature: the communication module is configured to be communicatively coupled to a communication device at the site, so as to be communicatively coupled to the remote device via the communication device.

Those of ordinary skill in the art can understand and implement other variations to the disclosed embodiments by studying the specification, the disclosure, the accompanying drawings and the appended claims. In the claims, the word “comprise” does not exclude other elements or steps, and the word “a” or “an” does not exclude plurality. In practical application of the present disclosure, one component may perform functions of multiple technical features cited in the claims. Any reference signs in the claims should not be construed as limiting the scope.

While various aspects and embodiments of the present disclosure have been disclosed herein, other aspects and embodiments will be apparent to those skilled in the art. Modifications, equivalent substitutes, and combinations of various technical features of the partial discharge detection apparatus may be made by those skilled in the art on the basis of various aspects and embodiments described herein without departing from the spirit and scope of the present application. Various aspects and embodiments disclosed herein are for illustrative purposes only and are not intended to be limiting. The scope of protection and spirit of the present disclosure are defined by the appended claims.

1. A partial discharge detection apparatus for monitoring partial discharges of an electrical device within a site, the partial discharge detection apparatus comprising:
an acoustic detection module disposed within the site and configured to face the electrical device to detect a sound wave generated by the electrical device and generate a corresponding acoustic signal; and
a control module coupled to the acoustic detection module to receive the acoustic signal, the control module being configured to determine, based on the acoustic signal, whether a partial discharge has occurred in the electrical device;
wherein the acoustic detection module and the control module are communicatively coupled but electrically isolated from each other.

2. The apparatus according to claim 1, wherein the acoustic detection module and the control module are configured to be disposed inside and outside the site, respectively, and are coupled to each other by way of a communication cable, the communication cable being configured to extend between the inside of the site and the outside of the site to couple the acoustic detection module and the control module.

3. The apparatus according to claim 1, wherein the control module further comprises:
a signal processing module coupled to the acoustic detection module to receive the acoustic signal, the signal processing module being configured to determine, based on the acoustic signal, whether a partial discharge has occurred in the electrical device, and to generate an alarm notification in response to determining that a partial discharge has occurred in the electrical device; and
a communication module coupled to the signal processing module to receive the alarm notification, the communication module being communicatively coupled to a remote device to send the alarm notification to the remote device.

4. The apparatus according to claim 3, wherein the control module is further configured to evaluate, based on the acoustic signal, a type and/or intensity of the partial discharge occurring in the electrical device, and to send the evaluated type and/or intensity of the partial discharge to the remote device via the communication module.

5. The apparatus according to claim 1, wherein the control module comprises:
a frequency detection circuit configured to detect operating frequency information of an AC power supply that supplies power to the electrical device within the site,
wherein the control module is further configured to determine, based on the acoustic signal and the operating frequency information, whether a partial discharge has occurred in the electrical device.

6. The apparatus according to claim 1, wherein the acoustic detection module comprises a plurality of acoustic sensors, the plurality of acoustic sensors being disposed to respectively face different parts of the electrical device to respectively detect sound waves generated by the electrical device.

7. The apparatus according to claim 1, wherein the acoustic detection module comprises at least one acoustic sensor, the at least one acoustic sensor being mounted on a rotatable base to be rotated by the rotatable base to face different parts of the electrical device, thereby separately detecting, from different directions, the sound wave generated by the electrical device.

8. The apparatus according to claim 1, wherein the acoustic detection module comprises a sensor array having a plurality of acoustic sensors, the sensor array being configured to use a beamforming technique to detect the sound wave generated by the electrical device; and
wherein the control module is further configured to determine, based on the acoustic signal corresponding to the sound wave detected using the beamforming technique, a part of the electrical device where the partial discharge has occurred.

9. The apparatus according to claim 1, wherein the acoustic detection module is configured to receive an operating mode instruction from the control module, the operating mode instruction comprising a continuous detection mode instruction or an intermittent detection mode instruction,
wherein the acoustic detection module is configured to detect, at a first detection frequency and in response to receiving the continuous detection mode instruction, the sound wave generated by the electrical device; and
wherein the acoustic detection module is configured to detect, at a second detection frequency and in response to receiving the intermittent detection mode instruction, the sound wave generated by the electrical device, wherein the first detection frequency is higher than the second detection frequency.

10. The apparatus according to claim 9, wherein the control module is further configured to generate the intermittent detection mode instruction after the apparatus is powered on, and to send the intermittent detection mode instruction to the acoustic detection module.

11. The apparatus according to claim 9, wherein the control module is further configured to generate the continuous detection mode instruction in response to receiving an abnormal acoustic signal, and to send the continuous detection mode instruction to the acoustic detection module.

12. The apparatus according to claim 11, wherein the control module is further configured to, when the acoustic detection module is in the continuous detection mode and no partial discharge of the electrical device has been found within a predetermined operating time, generate the intermittent detection mode instruction, and send the intermittent detection mode instruction to the acoustic detection module.

13. The apparatus according to claim 1, wherein the acoustic detection module comprises a Σ-Δ modulator, the Σ-Δ modulator being configured to perform signal modulation on the acoustic signal using pulse density modulation to convert same from an analog signal format to a pulse density modulated digital signal format.

14. A method for monitoring partial discharges of an electrical device within a site by using a partial discharge detection apparatus, the partial discharge detection apparatus comprising an acoustic detection module and a control module communicatively coupled but electrically isolated from each other, the method comprising:
disposing at least the acoustic detection module of the partial discharge detection apparatus within the site and facing same toward the electrical device;
receiving, by the acoustic detection module, a sound wave generated by the electrical device and generating a corresponding acoustic signal; and
determining, by the control module based on the acoustic signal, whether a partial discharge has occurred in the electrical device.

15. The method according to claim 14, wherein the acoustic detection module and the control module are coupled to each other by way of a communication cable, wherein disposing at least the acoustic detection module of the partial discharge detection apparatus within the site and facing the acoustic detection module toward the electrical device comprises:
disposing the acoustic detection module and the control module inside and outside the site, respectively, and extending the communication cable between the inside of the site and the outside of the site.

16. The method according to claim 14, further comprising:
evaluating, by the control module based on the acoustic signal, a type and/or intensity of the partial discharge occurring in the electrical device; and
sending outwards, by the control module, the evaluated type and/or intensity of the partial discharge.

17. The method according to claim 14, further comprising:
coupling the partial discharge detection apparatus to an AC power supply supplying power to the electrical device within the site;
detecting, by the partial discharge detection apparatus, operating frequency information of the AC power supply; and
determining, by the control module based on the acoustic signal and the operating frequency information, whether a partial discharge has occurred in the electrical device.

18. The method according to claim 14, further comprising:
generating, by the control module, an operating mode instruction, wherein the operating mode instruction comprises a continuous detection mode instruction or an intermittent detection mode instruction; and
detecting, by the acoustic detection module at a first detection frequency and in response to the continuous detection mode instruction, the sound wave generated by the electrical device, or detecting, by the acoustic detection module at a second detection frequency and in response to the intermittent detection mode instruction, the sound wave generated by the electrical device, wherein the first detection frequency is higher than the second detection frequency.

19. The method according to claim 18, wherein generating, by the control module, the operating mode instruction comprises:
generating, by the control module, the intermittent detection mode instruction after the partial discharge detection apparatus is powered on.

20. The method according to claim 18, wherein generating, by the control module, the operating mode instruction comprises:
generating, by the control module in response to the acoustic detection module detecting an abnormal sound wave, the continuous detection mode instruction.

21. The method according to claim 20, wherein generating, by the control module, the operating mode instruction further comprises:
when the partial discharge detection apparatus is in the continuous detection mode and no partial discharge of the electrical device has been found within a predetermined operating time, generating, by the control module, the intermittent detection mode instruction.

22. A partial discharge detection apparatus for monitoring partial discharges of an electrical device within a site, the partial discharge detection apparatus comprising:
an acoustic detection module disposed within the site and configured to face the electrical device to detect a sound wave generated by the electrical device and generate a corresponding acoustic signal; and
a communication module coupled to the acoustic detection module to receive the acoustic signal, and configured to be communicatively coupled to a remote device to send the acoustic signal to the remote device, thereby allowing the remote device to determine, based on the acoustic signal, whether a partial discharge has occurred in the electrical device.

23. The apparatus according to claim 22, wherein the acoustic detection module comprises a sensor array having a plurality of acoustic sensors, the sensor array being configured to use a beamforming technique to detect the sound wave generated by the electrical device to allow the remote device to determine, based on the acoustic signal corresponding to the sound wave detected using the beamforming technique, a part of the electrical device where the partial discharge has occurred.

24. The apparatus according to claim 22, wherein the acoustic detection module is configured to receive an operating mode instruction from the remote device, the operating mode instruction comprising a continuous detection mode instruction or an intermittent detection mode instruction,
wherein the acoustic detection module is configured to detect, at a first detection frequency and in response to receiving the continuous detection mode instruction, the sound wave generated by the electrical device; and
the acoustic detection module is configured to detect, at a second detection frequency and in response to receiving the intermittent detection mode instruction, the sound wave generated by the electrical device, wherein the first detection frequency is higher than the second detection frequency.
